(19) United States
(12) Patent Application Publication
(10) Pub. No.: US 2020/0373494 A1
(43) Pub. Date: Nov. 26, 2020

(54) LIGHT-EMITTING LAYER-FORMING INK AND MANUFACTURING METHOD OF ORGANIC EL ELEMENT

(71) Applicant: JOLED Inc., Tokyo (JP)

(72) Inventors: Tomohiko ODA, Tokyo (JP); Shinichiro ISHINO, Tokyo (JP); Toshiyuki AKIYAMA, Tokyo (JP); Mineki HASEGAWA, Tokyo (JP); Yasuhiro SEKIMOTO, Tokyo (JP); Muneharu SATO, Tokyo (JP)

(73) Assignee: JOLED Inc., Tokyo (JP)

(21) Appl. No.: 16/877,509

(22) Filed: May 19, 2020

(30) Foreign Application Priority Data
May 20, 2019 (JP) 2019-094826
May 14, 2020 (JP) 2020-085446

(51) Int. Cl. H01L 51/00; H01L 51/56; C09D 11/033; C09K 11/02

(52) U.S. Cl. CPC H01L 51/0052; H01L 51/56; H01L 51/5012; C09K 11/025; C09D 11/033

(57) ABSTRACT

Disclosed is a light-emitting layer-forming ink useful in forming an organic light-emitting layer for an organic EL element by a printing process, including a tetralin-based organic solvent, and a solute including an anthracene-based, low molecular material and dissolved at a concentration of 3% or higher and 12% or lower in the tetralin-based organic solvent.

### CROSS-REFERENCE TO RELATED APPLICATIONS

The present disclosure contains subject matter related to that disclosed in Japanese Priority Patent Application Nos. JP 2019-094826, filed May 20, 2019, and JP 2020-085446, filed May 14, 2020, the entire content of each is hereby incorporated by reference.

### BACKGROUND

The present disclosure relates to a blue light-emitting layer-forming ink useful in forming an organic light-emitting layer for an organic electroluminescent (hereinafter abbreviated as “EL”) element by a printing process, and also to a manufacturing method of the organic EL element by using the blue light-emitting layer-forming ink.

In recent years, active developments have been made in organic EL display panels that use light emission of organic EL elements. An organic EL element includes a pixel electrode (first electrode) for each pixel, an organic functional layer including an organic light-emitting layer, and an opposite electrode (second electrode) common to a plurality of organic EL elements in this order above a substrate, and holes and electrons supplied from the pixel electrode and the opposite electrode, respectively, recombine in the organic light-emitting layer so that an organic light-emitting material emits light.

Examples of a formation method of organic light-emitting layers for an organic EL display panel include a deposition process and a printing process (see, for example, JP 2009-237299 A). According to the printing process, a solution with an organic material dissolved in a solvent (hereinafter simply called “ink”) is prepared, and the ink is then coated onto the target area on the substrate by a printing process or the like. After the coating, the solvent is evaporated and dried from the ink to form an organic layer. Therefore, the printing process does not require to conduct the process in a vacuum vessel, and is considered to be preferred for mass production.

In the printing process, the ink is required not to deteriorate in conditions with time while retaining its initial state of dissolution over a long period of time. In general, high-molecular light-emitting materials easily soluble in organic solvents have hence been used as solutes.

Following a move toward higher-definition organic EL panels in recent years, it is required to reduce the nozzle size of a printing machine when the printing process is used. In addition, with a move toward a reduction in ink dropping amount, it is also required to make higher the concentration of an ink so that an organic light-emitting layer of a required thickness is formed.

### SUMMARY

Nonetheless, a high molecular material used as a solute in an ink involves a problem that, if the concentration of the ink is made higher, the ink abruptly increases in viscosity, clogs in the nozzle of a printing machine, and can no longer be ejected normally.

As disclosed in WO 2008/105472 A1, it has therefore been proposed to employ a light-emitting layer-forming ink that uses a low molecular light-emitting material as a solute. However, the low molecular light-emitting material has lower solubility in an organic solvent than a high molecular material. Furthermore, a low-molecular blue light-emitting materials have a problem in dissolution stability when the ink concentration increases, and involves a risk that due to occurrence of precipitates in an ink during long-term storage, the ink clogs in the nozzle of a printing machine, and can no longer be ejected normally.

The disclosure has been developed with the foregoing circumstances in view, and has as objects thereof the provision of a blue light-emitting layer-forming ink, which is useful in forming an organic light-emitting layer by a printing process and which does not substantially increase in viscosity even at high ink concentration, is suppressed from clogging in the nozzle of a printing machine, and despite the use of a low molecular light-emitting material, is also excellent in dissolution stability, and also the provision of a manufacturing method of an organic EL element by using the light-emitting layer-forming ink.

A light-emitting layer-forming ink according to a first aspect of the disclosure is useful in forming an organic light-emitting layer for an organic EL element that emits blue light by a printing process, and contains a tetralin-based organic solvent, and a solute including an anthracene-based, low molecular material and dissolved at a concentration of 3% or higher and 12% or lower in the tetralin-based organic solvent.

Further, a manufacturing method, according to a second aspect of the present disclosure, of an organic EL element that emits blue light includes a first step of providing a substrate, a second step of arranging a first electrode above the substrate, a third step of forming an organic light-emitting layer above the first electrode, and a fourth step of forming a second electrode above the organic light-emitting layer. The third step includes a coating step of coating a blue light-emitting layer-forming ink, and a drying step of drying the coated blue light-emitting layer-forming ink. The light-emitting layer-forming ink contains a tetralin-based organic solvent, and a solute including an anthracene-based, low molecular material and dissolved at a concentration of 3% or higher and 12% or lower in the tetralin-based organic solvent.

With the blue light-emitting layer-forming ink according to the first aspect, the viscosity can be controlled sufficiently low compared with the use of a high molecular light-emitting material, the occurrence of ink clogging in the nozzle of a printing machine can be prevented, high dissolution stability can be maintained over a long period even at a high ink concentration, and therefore a high-quality and high-definition organic EL element that emits blue light can be manufactured.

### BRIEF DESCRIPTION OF THE DRAWINGS

FIG. 1 is a table presenting the experimental results of dissolution stability at 3% ink concentration in individual solvent species two weeks later, one month later and three months later when an anthracene-based light-emitting material was used as a solute;

FIG. 2 is a table presenting, in the Hansen space, the center coordinates and R0 value of the solute and Ra and RED values that indicate positional relationships between the solute and individual solvents;

FIG. 3 is a table presenting the examination results of upper limit concentrations of the solute in four solvent species, at which the solubility of the solute can remains for three months;

FIG. 4 is a graph presenting the relationship between ink concentration and viscosity when a low molecular material and a high molecular material were used as solutes, respectively;

FIG. 5 is a table presenting the states of dissolution and the results of ejection by a printing machine at 10% ink concentration when the low molecular material and the high molecular material were used as solutes, respectively;

FIG. 6 is a schematic diagram illustrating the stacked structure of an organic EL element, which used a blue light-emitting layer ink according to an embodiment and was provided for its evaluation;

FIG. 7 is a table presenting various characteristics of the organic EL element;

FIGS. 8A and 8B illustrate the structural formulas representing examples of the anthracene-based light-emitting material;

FIGS. 9A and 9B illustrate the structural formulas representing other examples of the anthracene-based light-emitting material;

FIG. 10 is a table presenting the structural formulas of individual examples (a) to (f) of the tetralin-based solvent species;

FIG. 11 is a fragmentary cross-sectional view specifically illustrating the stacked structure of an organic EL element that emits blue light;

FIGS. 12A and 12B are schematic diagrams illustrating formation steps of a light-emitting layer in manufacturing steps of the organic EL element that emits blue light; and

FIG. 13 is a flow chart illustrating the manufacturing steps of the organic EL element that emits blue light according to the embodiment.

### DETAILED DESCRIPTION OF THE PREFERRED EMBODIMENT

### <<Circumstances LED to an Embodiment of the Disclosure>>

As a process for the formation of a light-emitting layer for each organic EL element in an organic EL display panel, coating that uses a printing machine or the like is superior in manufacturing cost to deposition such as vacuum deposition.

On the other hand, a strong demand has recently arisen for a still higher definition in organic EL display panels. To meet this demand, there is an urgent need for the development of a high-definition light-emitting layer-forming ink. To respond this need, however, there are problems to be overcome.

First, in order to print a pattern of a high-definition light-emitting layer, the nozzle size of a printing machine has to be reduced, and moreover the droplet amount of an ink that can be ejected in the form of the pattern has to be decreased. For the realization of a film thickness as required, it is hence desired to increase the concentration of an organic light-emitting material in the ink.

JP 2018-085257 A presents, in FIG. 7, a relationship diagram between the definition of an organic EL display panel and the ink concentration for the formation of a predetermined thickness in a light-emitting layer by ejection of ink droplets from a printing machine. From the relationship diagram, it is appreciated that an ink concentration of 3% or higher is needed for performing coating in a pattern of 80 ppi or higher definition.

According to JP 2019-16458 A, on the other hand, thickening of a light-emitting layer is required for the optimization of light extraction effect, so that its thickness needs to be at most 130 nm. To obtain this thickness by a droplet ejection method that uses a printing machine, an ink needs to have a concentration of 12%. In order to form a light-emitting layer by droplet ejection to such a thickness as to provide, for example, an increased light extraction efficiency in an organic EL panel having a certain level of definition or higher, an ink having a concentration of 3% or higher and at most 12% is desired accordingly (First Condition).

Second, the viscosity of an ink generally becomes higher with its concentration. However, the nozzle size of a printing machine is very small. In order to prevent clogging of the ink in a nozzle, the ink is desired to have a viscosity of 12 mPa·s or lower.

If an ink conversely has a viscosity of lower than 2 mPa·s, the ink tends to form satellites (a phenomenon that ink droplets break up) upon ejection, thereby making it difficult to accurately apply the ink onto a target pattern.

Therefore, the viscosity of an ink is desirably 2 mPa·s or higher and 12 mPa·s or lower (Second Condition).

Third, as an ink for organic EL elements, the period in which the initial dissolution state of the ink can stably remain without precipitation of the solute (hereinafter referred to as “stable dissolution period”) is desirably long, specifically at least three months (Third Condition).

The longer the stable dissolution period of a formulated ink, the more the ink clogging in the nozzle of a printing machine by precipitates from the ink can be prevented. Accordingly, an ink having a long stable dissolution period is superior in quality control and manufacturing cost.

At present, however, there is no blue light-emitting layer-forming ink that satisfies all the first to third conditions. The present inventors have conducted a great deal of research with a view to obtaining a blue light-emitting layer-forming ink that satisfies the above-described conditions, and as a result have led to the first and second aspects of the disclosure.

### <<Outline of First Aspect of the Disclosure>>

The blue light-emitting layer-forming ink according to the first aspect of the disclosure is useful in forming an organic light-emitting layer for an organic EL element that emits blue light by a printing process, and contains a tetralin-based organic solvent, and a solute including an anthracene-based, low molecular material and dissolved at a concentration of 3% or higher and 12% or lower in the tetralin-based organic solvent.

With the blue light-emitting layer-forming ink according to the first aspect, the viscosity can be controlled sufficiently low compared with the use of a high molecular light-emitting material, the occurrence of ink clogging in the nozzle of a printing machine can be suppressed even if the nozzle size is reduced, and a blue light-emitting layer can be formed with a required thickness. Further, high dissolution stability can be maintained over a relatively long period at a high ink concentration, and therefore a light-emitting layer can be formed for a high-quality and high-definition organic EL element that emits blue light.

In a preferred example of the first aspect of the disclosure, the solute with the anthracene-based, low molecular material included therein may be dissolved at a concentration of higher than 7% and 12% or lower in the tetralin-based organic solvent.

In another preferred example of the first aspect of the disclosure, the anthracene-based, low molecular material may have a weight average molecular weight of not higher than 3,000.

According to such preferred examples, even in the case of an ink having a high concentration, its viscosity can fall within such a range that the ink can be ejected by a printing machine.

Here, the tetralin-based organic solvent may be 1,2,3,4-tetrahydronaphthalene.

A manufacturing method according to the second aspect of the disclosure for an organic EL element that emits blue light includes a first step of providing a substrate, a second step of arranging a first electrode above the substrate, a third step of forming an organic light-emitting layer above the first electrode, and a fourth step of forming a second electrode above the organic light-emitting layer. The third step includes a coating step of coating a blue light-emitting layer-forming ink, and a drying step of drying the coated blue light-emitting layer-forming ink. The blue light-emitting layer-forming ink contains a tetralin-based organic solvent, and a solute including an anthracene-based, low molecular material and dissolved at a concentration of 3% or higher and 12% or lower in the tetralin-based organic solvent.

According to the second aspect, a high-quality and high-definition, organic EL element that emits blue light can be manufactured with a light-emitting layer formed by a printing process.

Here, the tetralin-based organic solvent may be 1,2,3,4-tetrahydronaphthalene.

Concerning each organic EL element in this specification, the term “above” does not indicate an upward direction (vertically above) in absolute spatial awareness, but is defined by a relative positional relationship based on the order of stacking in the stacked structure of the organic EL element. Described specifically, a direction that is vertical to a principal plane of a substrate and is on a side directed from the substrate toward the side of a stack is defined to be an upward direction. Where expressed as “above a substrate,” this expression should indicate not only a region which is in direct contact with the substrate but also a region over the substrate with a stack interposed therebetween. Further, each expression “ink concentration [%]” as used herein means “the weight percent (wt %)” of a solute dissolved in a solvent.

### Embodiment

### <Composition of Light-Emitting Layer-Forming Ink>

### 1. Solute

A blue light-emitting layer-forming ink according to this embodiment uses, as a solute, an anthracene-based organic material that has a low molecular weight.

Here, the term “anthracene-based organic material” means an organic material that contains an anthracene moiety represented by the following formula (1):

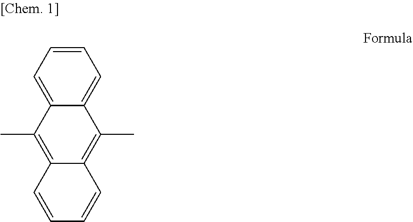

However, an excessively large molecular weight tends to lead to an abrupt increase in viscosity with an increase in ink concentration, so that a low molecular weight is desired. If the molecular weight is high, it is considered that molecules are prone to tangle together with an increase in ink concentration and the viscosity hence tends to increase.

From a quantitative viewpoint, the term “low molecular” in this embodiment desirably means that the molecular weight Mw (weight average molecular weight) is not higher than 3,000.

As a reason for this desire, it is possible to observe that compared with a high molecular material, the viscosity is suppressed from abruptly increasing with an increase in ink concentration if the molecular weight Mw is not higher than 3,000.

The molecular weight Mw of an organic material can be measured using known gel permeation chromatography (low molecular GPC) or liquid chromatography (LC).

### 2. Solvent

In this embodiment, an organic solvent (tetralin-based organic solvent) having the tetralin skeleton represented by the following formula (2) is adopted as a solvent for the ink.

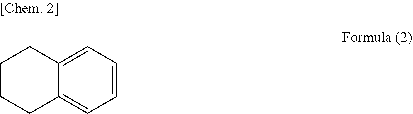

### <Evaluation of Dissolution Stability>

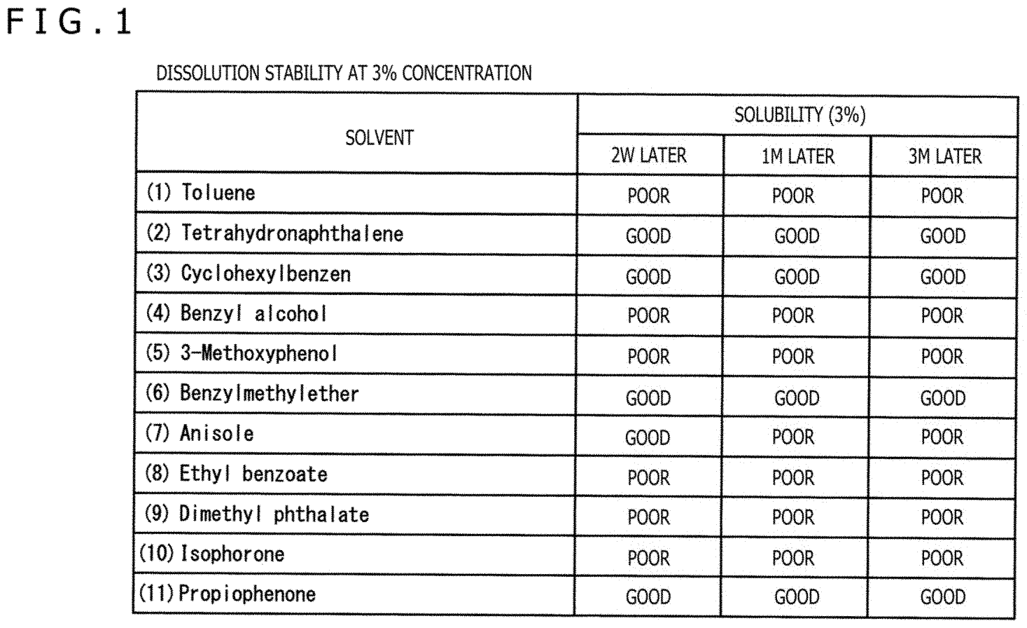

FIG. 1 is a table presenting the experimental results of dissolution stability of the above-described anthracene-based solute of the low molecular weight in various solvents.

In this embodiment, an experiment was conducted using, as the anthracene-based solute, an organic material containing the basic moiety represented by the formula (1) (hereinafter simply called “the anthracene-based material”).

For ink formation, a known shaker was first rotated at 100 rpm for 24 hours while maintaining the temperature at 60° C., whereby an ink of 3% concentration was formulated.

Subsequently, the ink was stored in a N₂ desiccator while being maintained at room temperature (25° C.), and a period during which the ink concentration stably remained was counted. A change in ink concentration was determined by visually observing precipitation of the solute.

As presented in the table of FIG. 1, many solvents were unable to maintain an ink concentration of 3% due to precipitation of the solute two weeks (2W) later or one month (1M) later, and therefore were poor in dissolution stability. On the other hand, four solvent species of tetrahydronaphthalene (2), cyclohexylbenzene (3), benzyl methyl ether (6) and propiophenone (11) were free from precipitation even three months (3M) later, and were able to maintain the ink concentration of 3%.

Mainstream solutes in blue light-emitting layer-forming inks for the conventional printing process are high-molecular materials. Concerning anthracene-based low molecular materials as in the disclosure, no attempt has heretofore been made about the dissolution stability at 3% ink concentration, and therefore the use of such anthracene-based low molecular materials is considered to be a new discovery.

In particular, according to analyses of the Hansen solubility parameters (hereinafter abbreviated as “HSP”), the dissolving power of tetralin (formal chemical name: 1,2,3,4-tetrahydronaphthalene) has been considered not so desirable for anthracene-based organic materials.

In general, HSP are often used as evaluation indices of the stability of solvents in the field of ink developments. In a sense, it has been a common practice to proceed with ink developments while referring to such HSP.

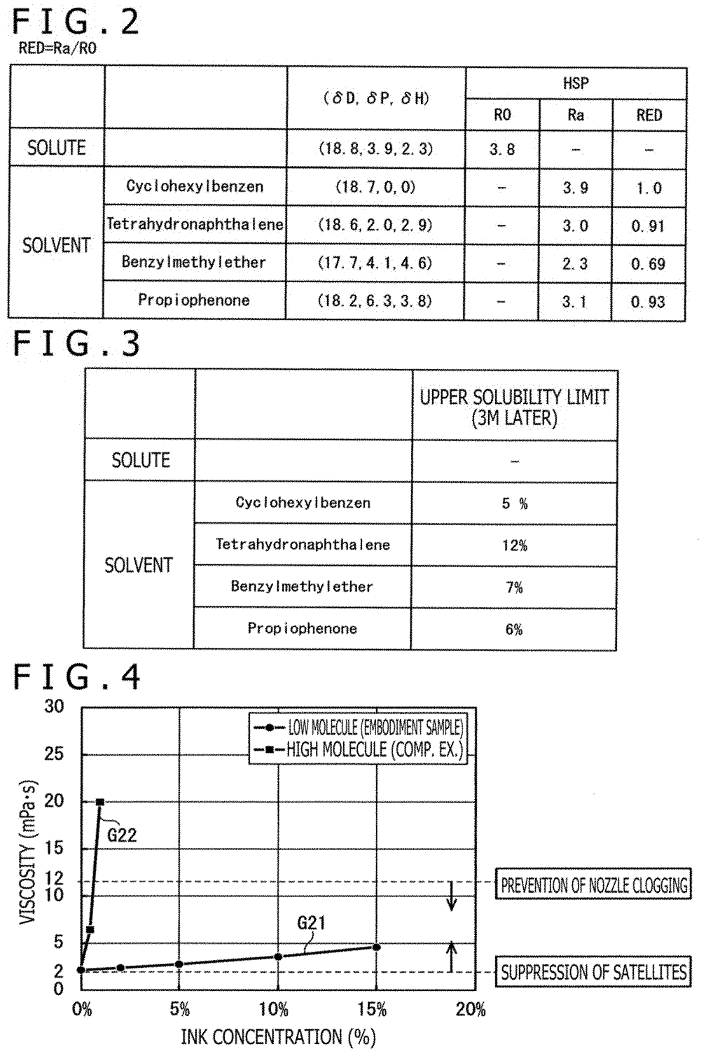

FIG. 2 is a table presenting, in the Hansen space, the center coordinates and RO value of the solute and Ra and RED values that indicate positional relationships between the solute and individual solvents.

The HSP use three parameters of energy (δD) by London dispersion force, energy (δP) by dipole interaction, and energy (δH) by hydrogen bonding.

The HSP are a vector quantity represented as (δD, δP, δH), and are expressed by plotting the vector quantity on a three-dimensional space (Hansen space) defined by coordinate axes of the three parameters of the HSP. The unit of each parameter is (J/cm³)^{1/2} (for details, refer to internet URL <http://hansen-solubility.com/>, for example).

For the HSP of commonly employed substances, a database has been compiled. By referring to the database, the HSP of a desired substance can be obtained. Concerning a substance whose HSP are not registered in the database, its HSP can be calculated from its chemical structure by using a computer software such as, for example, the Hansen Solubility Parameters in Practice (HSPiP).

The relative energy difference (RED) is expressed by the following formula (3):

RED=Ra/R0 (3)

where Ra is the distance between the HSP of a solute and the HSP of a solvent, that is, the HSP distance, and R0 is the interaction radius of the solute.

Ra (HSP distance) is expressed by the following formula (4):

Ra={4(δDS−δDL)²+(δPS−δPL)²+(δHS−δHL)²}^{0.5} (4)

where δDS is the energy of London dispersion forces of the solute, δPS is the energy by dipole interaction of the solute, δHS is the energy of hydrogen bonding of the solute, δDL is the energy of London dispersion forces of the solvent, δPL is the energy by dipole interaction of the solvent, and δHL is the energy of hydrogen bonding of the solvent.

R0 (the interaction radius of the solute) is determined, for example, by the following method. First, the solute whose R0 is to be determined and several kinds of solvents whose HSP are already known are provided. A solubility test of the solute is then carried out in each solvent. The HSP of the solvents which have exhibited dissolving power and the HSP of the solvents which have exhibited no dissolving power, all in such solubility tests, are plotted, respectively, in the Hansen space. Based on the HSP of the respective solvents so plotted, a virtual sphere (Hansen sphere) is formed in the Hansen space so that the virtual sphere (Hansen sphere) includes the HSP of the solvents, which exhibited dissolving power, but does not include the HSP of the solvents, which exhibited no dissolving power. The radius of the Hansen sphere is R0.

R0 is dependent on the concentration of the solution. If the solute is added to a solvent to prepare a high concentration solution and a low concentration solution, respectively, for example, the solute contained in the high concentration solution has a relatively smaller R0 than the solute contained in the low concentration solution. Further, as the period of dissolution becomes longer, precipitates are more prone to be successively formed from solutions of the solute in solvents in the order of the distances of the solvents from the center coordinates of the solute, and the Hansen sphere tends to have a smaller radius.

FIG. 2 is the table presenting the center coordinates of the Hansen sphere and R0 (the interaction radius of the solute) relating to the anthracene-based solute and the Ra and RED values indicating the positional relationships between the solute and the various solvents, all, determined under the following conditions: at 3% ink concentration, and after an elapse of three months.

According to the Hansen's analysis theorem, higher dissolution stability is exhibited as the RED comes closer to 0, in other words, as a solvent has Hansen coordinates closer to the center coordinates of the Hansen sphere of a solute.

According to the analysis results presented in FIG. 2, tetrahydronaphthalene, that is, tetralin has a RED value which is 0.91 in the HSP space and exists inside the Hansen sphere. However, the RED value is substantially near the spherical surface (in other word, the RED is close to 1) so that according to the Hansen's analysis theorem, the solubility of the anthracene-based material in tetralin cannot be expected much.

In general, a low-molecular organic EL material tends have a lower solubility in an organic solvent compared with a high-molecular organic material. Nonetheless, it has been considered that even in an ink suited for organic EL elements and containing a low-molecular organic material and an organic solvent, the solubility and dissolution stability of the low-molecular organic material have been considered to be improved by setting the RED at smaller than 0.5 like a high-molecular organic material.

Practically, however, despite that the RED of tetralin is close to “1” as presented in FIG. 4, it was possible with the anthracene-base material to obtain a stable dissolution period as long as three months at 3% ink concentration as indicated in the experimental results of FIG. 4. This is a peculiar trend.

Accordingly, effects on dissolution stability were also studied with respect to the four species of solvents, which were able to maintain the stable dissolution period of three months at 3% concentration, in the experiment of FIG. 1.

FIG. 3 is a table presenting, in regard to each of the solvent species, the upper limit value of an ink concentration at which the solute (anthracene-based material) did not precipitate even upon an elapsed time of three months after the preparation of the ink.

As presented in the table, an ink concentration of 5% was an upper limit for cyclohexylbenzene, an ink concentration of 6% was an upper limit for propiophenone, and an ink concentration of 7% was an upper limit for benzyl methyl ether. With respect to tetralin, on the other hand, the solute did not precipitate for three months even at an ink concentration of 12%, and exhibited superb dissolution stability.

The peculiar characteristic that a solute exhibits a high degree of dissolution stability irrespective of its low molecular weight as described above is considered to be attributed to the chemical compatibility between the anthracene-based material as a solute and tetralin as a solvent. At present, however, it is difficult to elucidate the peculiar characteristic to such an extent as its specific principle.

### <Evaluation of Ink Viscosity>

FIG. 4 is a graph presenting the relationship between ink concentration and viscosity. Ink concentrations (%) are plotted along the axis of abscissas, while viscosities (mPa·s) are plotted along the axis of ordinates. A line G21 indicates changes of the viscosity of the ink (solute: anthracene-based material, solvent: tetralin) according to this embodiment. A line G22 indicates, as a comparative example, changes in the viscosity of an ink of a high-molecular material described in WO 2012/001744 A1.

As already mentioned, in a printing machine capable of dropping an ink in minute volumes for a higher definition, the upper limit of the ink concentration is needed to be 12 mPa·s for the prevention of nozzle plugging, and the lower limit of the ink concentration is desired to be 2 mPa·s for the suppression of occurrence of satellites (break-up of ink droplets before reaching a target) so that the accuracy of printing is maintained (this viscosity range of 2 mPa·s or higher and 12 mPa·s or lower will hereinafter be referred to as “the optimal viscosity range”).

In the comparative example (the line G22), the solute was the high-molecular material, and therefore the viscosity abruptly increased and already exceeded the optimal viscosity range even at an ink concentration as low as 1% or so.

In the ink according to this embodiment (the line G21), however, the viscosity remained within the optimal viscosity range until the ink concentration increased to 12%, whereby dropping of the ink in minute volumes was possible.

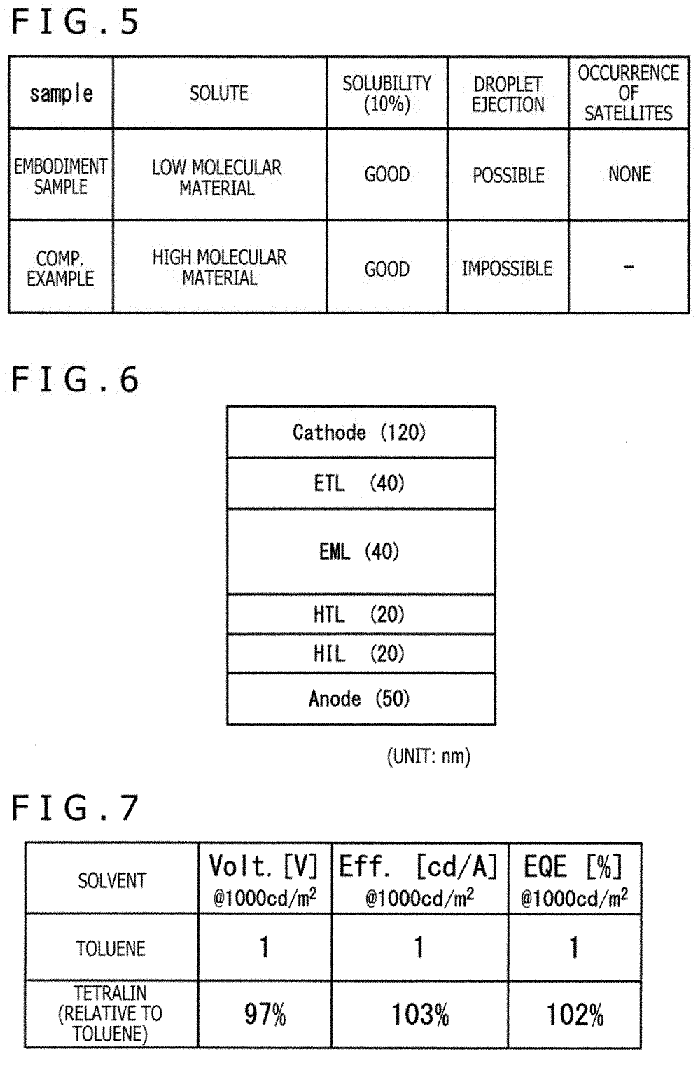

FIG. 5 is a table presenting the states of dissolution and the results of ejection of droplets by a printing machine and occurrence of satellites when the ink concentration was 10%.

If a low-molecular material (anthracene-based material) and tetrahydronaphthalene (THN, tetralin) are used as a solute and a solvent, respectively, as in this embodiment (embodiment sample), the state of dissolution is good even at the ink concentration of 10% and the viscosity falls within the optimal viscosity range. Accordingly, ejection of droplets is possible, and no satellites occur.

If the solute is a high-molecular material as in the comparative example, the high-molecular material is dissolved at the ink concentration of 10%, but the viscosity considerably departs from the optimal viscosity range and ejection of droplets is impossible. This ink is therefore considered to be hardly usable as an ink for high-definition printing machines.

As has been described above, only when an anthracene-based material is used as a solute and tetralin is used as a solvent, it is possible to obtain a light-emitting layer-forming ink having, at an ink concentration of 3% to 12%, a viscosity within the optimal viscosity range suited for a high-definition printing apparatus, and also a long stable dissolution period. Such a blue light-emitting layer-forming ink did not exist to date.

### <Light-Emitting Characteristics of Light-Emitting Layer>

Evaluations will next be made about light-emitting characteristics when a light-emitting layer for a blue-emitting organic EL element was formed using the blue light-emitting layer-forming ink according to this embodiment.

FIG. 6 is a schematic diagram illustrating the stacked structure of the organic EL element as a target of the evaluations.

The organic EL element was manufactured by stacking a hole injection layer (HIL) and a hole transport layer (HTL) each with a thickness of 20 nm on a positive electrode (anode) of 50 nm thickness, applying an ink, which contained the anthracene-based material as a solute and tetralin as a solvent and had a concentration of 3%, on the HTL and drying the ink to form a light-emitting layer of 40 nm thickness (see the table of FIG. 2), forming an electron transport layer (ETL) with a thickness of 40 nm on the light-emitting layer, and further forming a negative electrode (cathode) of a transparent conductive material such as IZO or ITO with a thickness of 120 nm.

FIG. 7 is a table presenting as the percentages of relative values of performances in tetralin solvent to performances in toluene solvent in terms of drive voltage (Volt [V]), emission efficiency (EFF. [cd/A]) and external quantum efficiency (EQE [%]), in which the performances in the toluene solvents were each assumed to be 1, when the luminance was 1,000 d/m² in the organic EL element as the target of evaluations.

All the results were equal or better compared with those obtained when toluene was used as a solvent.

From the foregoing, the use of the anthracene-based material as a solute in combination with tetralin as a solvent presumably has no problem of deteriorating the light-emitting characteristics of a light-emitting layer even if the ink concentration is increased further. In this respect, the anthracene-based material is also considered to be an excellent ink material.

### <Other Anthracene-Based Light-Emitting Materials>

In the foregoing, the description has been made solely of the anthracene-based material as a solute for the blue light-emitting layer-forming ink. Insofar as the anthracene moiety represented by the formula (1) is contained, other light-emitting materials (hereinafter referred to as “anthracene-based light-emitting materials”) are also usable without being limited to the anthracene-based material because, insofar as the anthracene moiety is contained in a solute, the solute has good compatibility with tetralin and a good state of dissolution is available.

If an anthracene-based, light-emitting material contains many substituent groups and has a greater molecular weight, however, the anthracene-based, light-emitting material becomes resembling a high-molecular material, leading to an increased ink viscosity that may depart from the optimal viscosity range. Therefore, the molecular weight Mw may desirably be not higher than 3,000 as mentioned above.

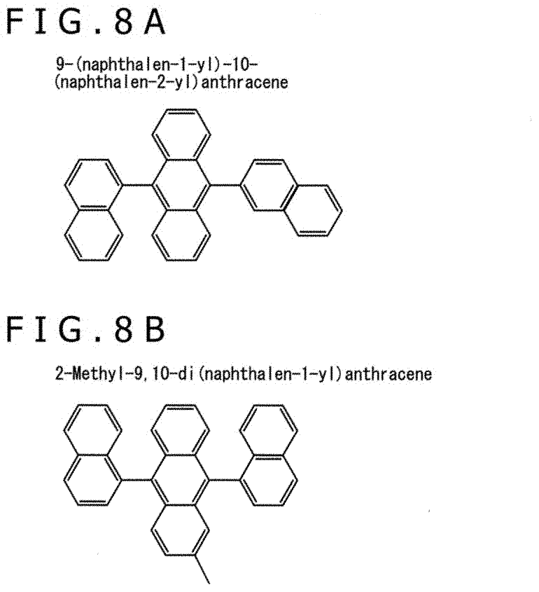

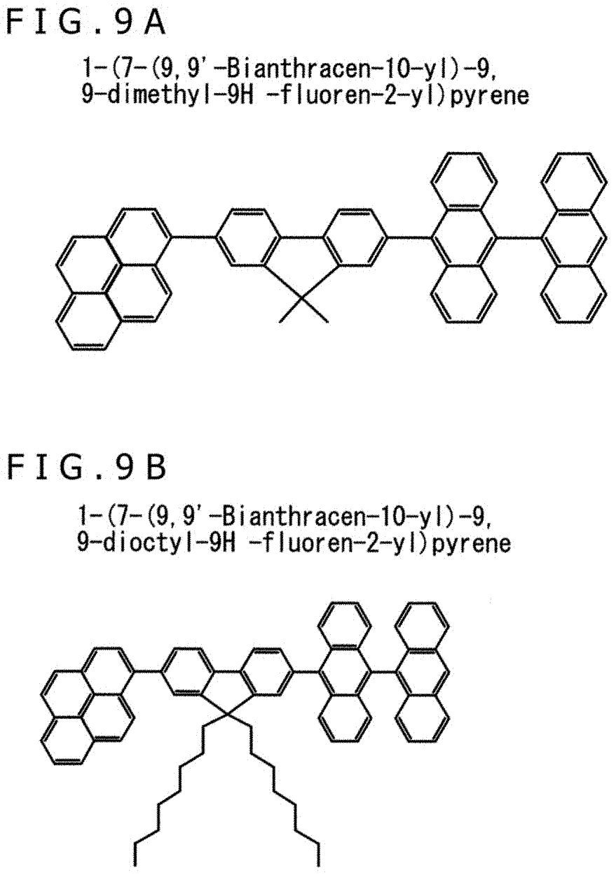

FIGS. 8A and 8B and FIGS. 9A and 9B illustrate examples of anthracene-based, light-emitting materials which meet such a condition.

Among the anthracene-based material of the formula (1) and the anthracene-based, light-emitting materials illustrated in FIGS. 8A and 8B and FIGS. 9A and 9B, two or more light-emitting materials may be combined as a solute.

### <Other Tetralin-Based Solvents>

In the foregoing, the description has been made solely of tetralin (1,2,3,4-tetrahydronaphthalene) as the solvent for the blue light-emitting layer-forming ink. Insofar as the tetralin skeleton represented by the formula (2) is contained, other solvents (hereinafter referred to as “tetralin-based solvents”) can also be used without being limited to tetralin. In other words, insofar as the tetralin skeleton is contained in a solvent, the solvent has good compatibility with the anthracene-based, light-emitting material as a solute, and a good state of dissolution is available.

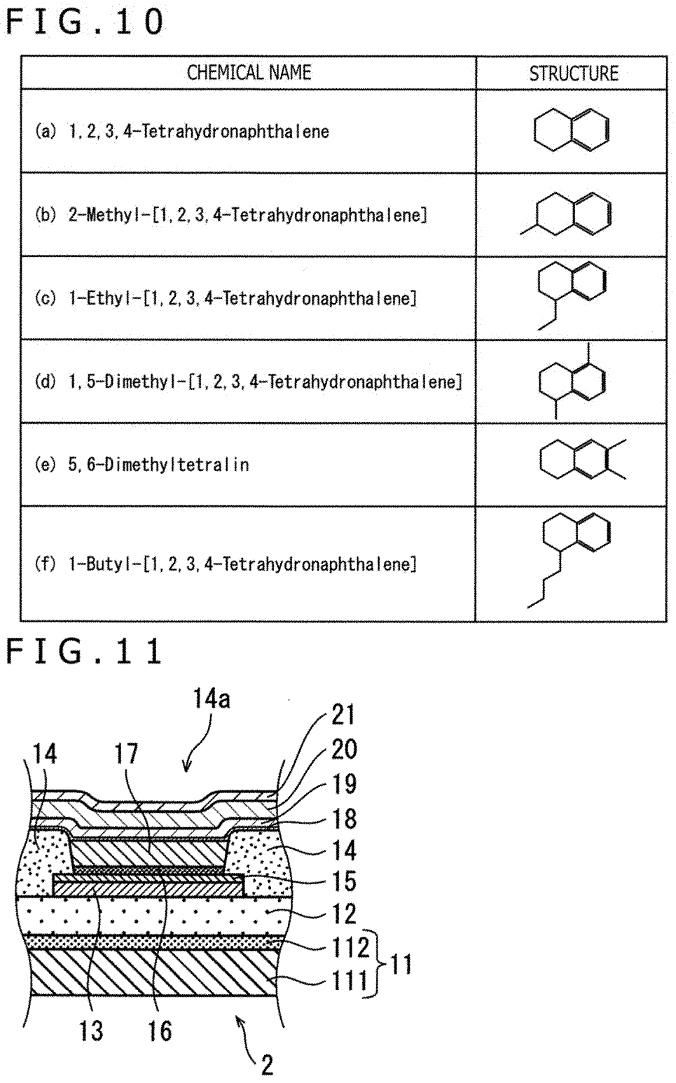

FIG. 10 presents specific examples (a) to (f) of such tetralin-based solvents.

As the solvent, two or more of the above-described plural tetralin-based solvents may be mixed, because they all contain the tetralin skeleton and all have compatibility with the anthracene-based, light-emitting material.

In the foregoing, the description has been made about the blue (B) light-emitting layer-forming ink. However, light-emitting materials of other colors may be added to an anthracene-based, light-emitting material, followed by dissolution in tetralin to prepare a red (R) light-emitting layer-forming ink and a green (G) light-emitting layer-forming ink.

Through an experiment, these red light-emitting layer-forming ink and green light-emitting layer-forming ink were found to have excellent characteristics as presented in Table 1 below.

TABLE 1
Dissolution Stability and Viscosity Measurement Results
of Inks of Individual Colors

| | Upper limit of soluble | Viscosity (ink |
|---|---|---|
| | concentration (three | concentration: |
| Color | months later) | 15%) (mPa · s) |
| Blue | 12% | 4.8 |
| Red | 18% | 4.7 |
| Green | 14% | 4.7 |

As presented in Table 1, the upper limit of soluble concentration of the blue and red light-emitting materials in the red-emitting ink after three months was 18% which was higher by as much as 6% than the upper limitation of soluble concentration of the blue-emitting ink, and the blue-emitting ink also exhibited 14% as the upper limit of soluble concentration of the blue and green light-emitting materials after three months.

In the initial stage of dissolution, it was possible to set the concentration of the ink of each color at 15%. The inks of the individual colors, whose concentrations were 15%, were hence measured for viscosity, and they were all found to have a viscosity of not higher than 4.8 mPa·s. The viscosity of an ink is known to decrease as the concentration decreases, and therefore the red-emitting ink and the green-emitting ink each fall within a viscosity range that can fully prevent clogging of a nozzle (see the graph of FIG. 4).

Although not described in Table 1, the viscosities of the red-emitting and blue-emitting inks at a concentration of 3% were 2 mPa·s or higher, at which the occurrence of satellites can be suppressed, like that of the blue-emitting ink as presented in FIG. 4.

Therefore, the use of a light-emitting layer-forming ink, which contains an anthracene-based, light-emitting material as a solute and a tetralin-based organic solvent as a solvent, can formulate individual color-emitting inks, which can maintain the upper limit of soluble concentration at 12% three months later and moreover have a viscosity suited for use in a printing machine at an ink concentration of 3% to 12%.

In the red-emitting ink in this experiment, the anthracene-based, light-emitting material and an iridium complex (ppy)₂Ir(acac) were used as solutes at a weight ratio of 9:1. In the blue-emitting ink, on the other hand, the anthracene-based, light-emitting material and an iridium complex (btp)₂Ir(acac) were used as solutes at a weight ratio of 9:1. To obtain a desired emission color, one or more light-emitting materials other than the above-described (ppy)₂Ir(acac) and (btp)₂Ir(acac) can be also added.

### <Configuration and Manufacturing Method of Organic EL Element>

With reference to the relevant figures of the drawings, a description will hereinafter be made about a specific configuration example of a top emission organic EL element, which used the light-emitting layer-forming ink according to the first aspect of the disclosure, and a manufacturing method thereof. The relevant figures include schematic ones, and the scale, vertical-to-horizontal scale ratio and the like of each member may be different from the actual ones.

### 1. Configuration of Organic EL Element

In an organic EL panel, each single pixel is generally formed from three subpixels that emit red (R), green (G) and blue (B), respectively. Each subpixel is configured of an organic EL element that emits light of the corresponding color.

The organic EL elements of the respective emission colors have a substantially similar configuration, and therefore a description will hereinafter be made about the configuration of an organic EL element 2 that emits blue light.

FIG. 11 is a fragmentary cross-sectional view schematically illustrating a stacked structure of the blue light emitting organic EL element 2. As illustrated in the figure, the organic EL element 2 is formed from a substrate 11, an interlayer insulating layer 12, a pixel electrode 13, banks 14, a hole injection layer 15, a hole transport layer 16, a light-emitting layer 17, an electron transport layer 18, an opposite electrode 20, and a sealing layer 21.

The substrate 11, the interlayer insulating layer 12, the electron transport layer 18, the electron injection layer 19, the opposite electrode 20, the sealing layer 21 are not formed for every subpixel, but are commonly formed for plural organic EL elements included in the organic EL panel.

### (1) Substrate

The substrate 11 includes a base substrate 111 of an insulating material, and a thin film transistor (TFT) layer 112. In the TFT layer 112, a drive circuit is formed for every subpixel. As the base substrate 111, it is possible to adopt, for example, a glass substrate, a quartz substrate, a silicon substrate, a metal substrate of molybdenum sulfide, copper, zinc, aluminum, stainless steel, magnesium, iron, nickel, gold, silver or the like, a semiconductor substrate of gallium arsenic or the like, a plastic substrate, or the like.

In the case of the plastic substrate, either a thermoplastic resin or a thermosetting resin may be used as a plastic material. Examples include various thermoplastic elastomers such as polyethylene, polypropylene, polyamides, polyimides (PI), polycarbonates, acrylic resins, polyethylene terephthalate (PET), polybutylene terephthalate, and polyacetals, and in addition, fluorine-containing resins, styrene-based resins, polyolefin-based resins, polyvinyl chloride resins, polyurethane resins, fluorinated rubbers and polyethylene chloride resins; epoxy resins, unsaturated polyesters, silicone resins, polyurethanes, and the like; and copolymers, polymer blends, polymer alloys and the like containing two or more of the above-exemplified materials as principal components. A base substrate formed from one of the above-exemplified materials or a laminate formed by laminating two or more of above-exemplified materials can be used.

For the manufacture of a flexible organic EL display panel, the substrate is preferably formed of a plastic material.

### (2) Interlayer Insulating Layer

The interlayer insulating layer 12 is formed on the substrate 11. The interlayer insulating layer 12 is formed from a resin material, and serves to flatten steps on the upper surface of the TFT layer 112. Examples of the resin material include positive photosensitive materials. Illustrative of such photosensitive materials are acrylic resins, polyimide-based resins, siloxane-based resins, and phenol-based resins. Although not illustrated in the cross-sectional view of FIG. 11, a contact hole is formed for every subpixel through the interlayer insulating layer 12.

### (3) Pixel Electrodes (First Electrodes)

The pixel electrodes 13 each include a metal layer formed from a light-reflective metal material, and are each formed on the interlayer insulating layer 12. Each pixel electrode 13 is disposed for every subpixel, and is electrically connected to the TFT layer 112 through the associated contact hole (not illustrated).

In this embodiment, the pixel electrodes 13 each function as an anode.

Specific examples of the metal material having light reflectivity include silver (Ag), aluminum (Al), aluminum alloys, molybdenum (Mo), silver-palladium-copper alloys (APCs), silver-rubidium-gold alloys (ARAs), molybdenum-chromium alloys (MoCrs), molybdenum-tungsten alloys (MoWs), nickel-chromium alloys (NiCrs), and the like.

Each pixel electrode 13 may be configured of the metal layer alone, but may also be formed into a stacked layer structure including a layer, which is composed from a metal oxide such as indium tin oxide (ITO) or indium zinc oxide (IZO), stacked on the metal layer.

### (4) Banks

The banks 14 are formed on the hole injection layer 15 in a state that each hole injection layer 15 is exposed at a region of an upper surface thereof, the hole injection layer 15 is covered by the banks 14 on the upper surface thereof at a region adjacent the exposed region, and the hole injection layer 15 and its associated pixel electrode 13 are covered on side surfaces thereof by the banks 14. On the upper surface of the hole injection layer 15, there is hence the region that is uncovered by the banks 14, in other words, is exposed. Over this uncovered region, the well 14a is formed.

In this embodiment, the banks 14 are formed on the interlayer insulating layer 12 at a portion thereof where the pixel electrode 13 is not formed. In other words, on a portion of the interlayer insulating layer 12 where the pixel electrode 13 is not formed, bottom surfaces of the banks 14 are in contact with an upper surface of the interlayer insulating layer 12. The banks 14 function as structures to prevent the applied ink from overflowing when the light-emitting layer 17 is formed by a wet process.

The banks 14 are formed, for example, from an insulating organic material (e.g., an acrylic resin, polyimide resin, siloxane resin, phenol resin, or the like). In this embodiment, a phenol resin is used.

### (5) Hole Injection Layers

Each hole injection layer 15 is disposed on the associated pixel electrode 13 to promote the injection of holes from the pixel electrode 13 into the corresponding light-emitting layer 17. The hole injection layers 15 are formed, for example, from an oxide of silver (Ag), molybdenum (Mo), chromium (Cr), vanadium (V), tungsten (W), nickel (Ni) or iridium (Ir) or a conductive polymer material such as a mixture of polythiophene and polystyrenesulfonic acid (PEDOT).

In this embodiment, the hole injection layers 15 are formed from PEDOT.

### (6) Hole Transport Layers

Each hole transport layer 16 has a function to transport holes, which have been injected from the associated hole injection layer 15, to the corresponding light-emitting layer 17. Using, for example, a high molecular compound containing no hydrophobic group such as polyfluorene or a derivative thereof or a polyarylamine or a derivative thereof, or the like, the hole transport layers 16 are formed by a wet process.

### (7) Light-Emitting Layers

Each light-emitting layer 17 is formed in the associated well 14a, and has a function to emit light of the corresponding one of the colors R, G, and B through recombination of holes and electrons.

In the present embodiment, the blue light-emitting layer including the anthracene represented by the above formula (1) and the anthracene-based low molecular materials shown in FIGS. 8(a), (b), 9(a), and (b).

In addition to the anthracene-based material, one or more other host materials, for example, one or more of amine compounds, fused polycyclic aromatic compounds, heterocompounds and the like are used. As the amine compounds, monoamine derivatives, diamine derivatives, triamine derivatives, and tetraamine derivatives are used, for example. Examples of the fused polycyclic aromatic compounds include naphthalene derivatives, naphthacene derivatives, phenanthrene derivatives, chrysene derivatives, fluoranthene derivatives, triphenylene derivatives, pentacene derivatives, perylene derivatives, and the like. Examples of the heterocompounds include carbazole derivatives, furan derivatives, pyridine derivatives, pyrimidine derivatives, triazine derivatives, imidazole derivatives, pyrazole derivatives, triazole derivatives, oxazole derivatives, oxadiazole derivatives, pyrrole derivatives, indole derivatives, azaindole derivatives, azacarbazole derivatives, pyrazoline derivatives, pyrazolone derivatives, phthalocyanine derivatives, and the like.

Usable examples of a dopant material for the light-emitting layer 17 to obtain a desired emission color include pyrene derivatives, fluoranthene derivatives, arylacetylene derivatives, fluorene derivatives, perylene derivatives, oxadiazole derivatives, and chrysene derivatives. As a dopant material for the light-emitting layer 17, a metal complex may also be used. Such a metal complex can be, for example, one having a metal atom of iridium (Ir), platinum (Pt), osmium (Os), gold (Au), rhenium (Re) or ruthenium (Ru), and a ligand.

### (8) Electron Transport Layer

The electron transport layer 18 has a function to transport electrons from the opposite electrode 20 to the light-emitting layers 17. The electron transport layer 18 is formed from an organic material having high electron transport properties, and contains neither an alkali metal nor an alkaline earth metal.

Examples of the organic material for use in the electron transport layer 18 include low molecular organic n-electron system materials such as oxadiazole derivatives (OXDs), triazole derivatives (TAZs), and phenanthroline derivatives (BCP, Bphen).

### (9) Electron Injection Layer

The electron injection layer 19 has a function to inject electrons, which have been supplied from the opposite electrode 20, toward the side of the light-emitting layer 17. The electron injection layer 19 is formed, for example, of an organic material having high electron transport properties and doped with a doping metal selected from alkali metals or alkaline earth metals.

Metals known as alkali metals are lithium (Li), sodium (Na), potassium (K), rubidium (Rb), cesium (Cs) and francium (Fr), and metals known as alkaline earth metals are calcium (Ca), strontium (Sr), barium (Ba) and radium (Ra).

In this embodiment, barium (Ba) is doped.

On the other hand, examples of the organic material for use in the electron injection layer 19 include low molecular organic n-electron system organic materials such as oxadiazole derivatives (OXDs), triazole derivatives (TAZs), and phenanthroline derivatives (BCP, Bphen).

### (10) Opposite Electrode (Second Electrode)

The opposite electrode 20 is formed from a transparent conductive material, and is formed on the electron injection layer 19. The opposite electrode 20 functions as a cathode.

As a material for the opposite electrode 20, a metal such as silver, a silver alloy, aluminum or an aluminum alloy may be used, for example. In such a case, the thickness may desirably range from 10 to 50 nm because the opposite electrode 20 needs to have transparency.

### (11) Sealing Layer

The sealing layer 21 is arranged to prevent deterioration of organic layers such as the hole transport layer 16, light-emitting layer 17, electron transport layer 18 and electron injection layer 19 through exposure to external water and/or air.

The sealing layer 21 is formed using, for example, a transparent material such as silicon nitride (SiN) or silicon oxynitride (SiON).

### (12) Others

Although not illustrated in FIG. 11, a color filter, which includes a glass substrate as a base substrate, and a polarizing sheet may be bonded onto the sealing layer 21 via an adhesive. By bonding them, the hole transport layer 16, light-emitting layer 17, electron transport layer 18 and electron injection layer 19 can be further protected from external water, air and/or the like.

### 2. Manufacturing Method of Organic EL Element

About a manufacturing method of the organic EL element that emits blue light 2, a description will hereinafter be made with reference to the relevant figures of the drawings.

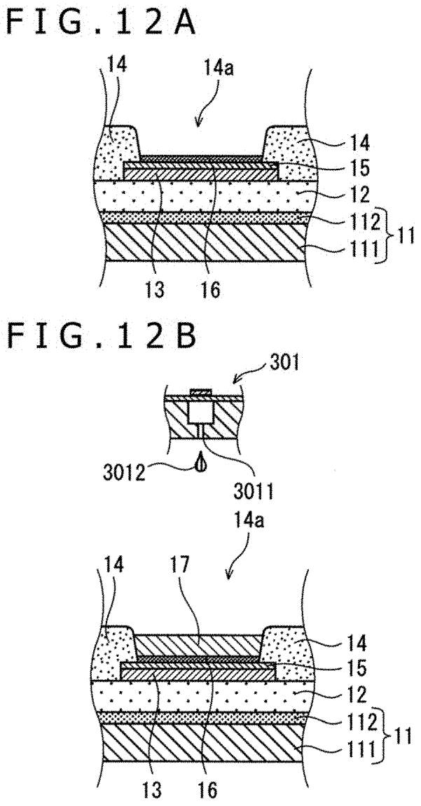

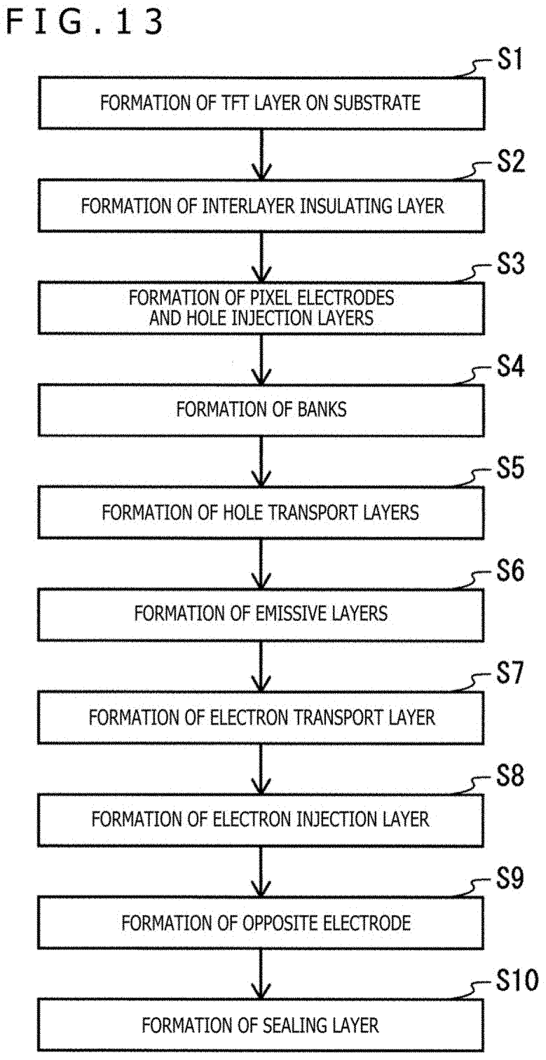

FIGS. 12A and 12B are schematic cross-sectional views for primarily describing formation steps of the light-emitting layer 17 in manufacturing steps of the organic EL element 2. FIG. 13 is a flow chart illustrating the manufacturing steps of the organic EL element 2.

### (1) Formation of Substrate 11

First, the TFT layer 112 is formed on the base substrate 111 to form the substrate 11 (Step S1 of FIG. 13). The TFT layer 112 can be formed by a known TFT manufacturing method.

The interlayer insulating layer 12 is next formed on the substrate 11 (Step S2 of FIG. 13).

Specifically, a resin material which has a certain degree of flowability is coated along an upper surface of the substrate 11, for example, by die coating so that the TFT layer 112 eliminates roughness on the substrate 11. As a consequence, the interlayer insulating layer 12 is provided at an upper surface thereof with a shape planarized along the upper surface of the base substrate 111.

Contact holes are next formed by applying dry etching to the interlayer insulating layer 12 at positions, for example, above source electrodes of the respective TFT elements. The contact holes are formed using patterning or the like so that surfaces of the source electrodes are exposed in bottom parts of the contact holes.

Connection electrode layers are next formed along inner walls of the contact holes. Upper portions of the connection electrode layers are disposed at parts thereof on the interlayer insulating layer 12. For the formation of the connection electrode layers, sputtering can be used, for example. After forming a metal film, patterning can be performed using photolithography and wet etching.

### (2) Formation of Pixel Electrodes 13 and Hole Injection Layers 15

The pixel electrodes 13 and hole injection layers 15 are next formed on the interlayer insulating layer 12 (Step S3 of FIG. 13).

On the interlayer insulating layer 12, a pixel electrode material layer of the material for the pixel electrodes 13 is first formed using, for example, vacuum deposition, sputtering or the like. A hole injection material layer 150 of the material for the hole injection layer 15 is next formed using, for example, reactive sputtering. A stacked film of the pixel electrode material layer and the hole injection material layer is thereafter patterned by etching to form the pixel electrodes 13 and hole injection layers 15 divided for every subpixel.

### (3) Formation of Banks 14

A solution with a phenol resin dissolved as a bank-forming resin in a solvent (for example, a mixed solvent of ethyl lactate and γ-butyrolactone (GBL)) is next uniformly applied on the hole injection layer 15 and interlayer insulating layer 12 by using spin coating or the like, whereby a bank material layer is formed. Pattern exposure and development are then applied to the bank material layer to form the banks 14 (Step S4 of FIG. 13).

### (4) Formation of Hole Transport Layers 16

By a printing machine, an ink which contains component materials for the hole injection layers 16 is next ejected into the individual openings 14a defined by the banks 14 so that the ink is applied onto the respective hole injection layers 15 in the openings 14a. The ink is then dried to form the hole transport layers 16 (see FIG. 12A) (Step S5 of FIG. 13).

### (5) Formation of Light-emitting Layers 17

As illustrated in FIG. 12B, the blue light-emitting layer-forming ink (ink concentration: 3%) according to the embodiment is ejected in a predetermined amount as droplets 3012 from a nozzle 3011 of a coating head 301 of the printing machine onto the hole transport layers 16 in the individual openings 14a. The ink is then dried to form the blue light-emitting layers 17 (Step S6 of FIG. 13). It is to be noted that in FIG. 12B, only one of the droplets 3012 is illustrated.

Desirably, the drying of the light-emitting layers 17 is conducted in a vacuum drier so that the light-emitting layers 17 have as a uniform thickness as possible.

### (6) Formation of Electron Transport Layer 18

The electron transport layer 18 is next formed on the light-emitting layers 17 and the banks 14 (Step S7 of FIG. 13). The electron transport layer 18 is formed, for example, through deposition of an electron transport organic material into a film common to individual subpixels by deposition.

### (7) Formation of Electron Injection Layer 19

The electron injection layer 19 is next formed on the electron transport layer 18 (Step S8 of FIG. 13). The electron injection layer 19 is formed, for example, through deposition of an electron transport organic material and a doping metal into a film common to the individual subpixels by co-deposition.

### (8) Formation of Opposite Electrode 20

The opposite electrode 20 is next formed on the electron injection layer 19 (Step S9 of FIG. 13). The opposite electrode 20 is formed through deposition of ITO, IZO, silver, aluminum or the like by sputtering or vacuum deposition.

### (9) Formation of Sealing Layer 21

The sealing layer 21 is next formed on the opposite electrode 20 (Step S10 of FIG. 13). The sealing layer 21 can be formed through deposition of SiON, SiN or the like by sputtering, CVD or the like.

As a consequence, the organic EL element 2 has been completed.

### <<Modifications>>

As the first and second aspects of the disclosure, the formula of the blue light-emitting layer-forming ink for the organic EL element that emits blue light and the manufacturing method of the organic EL element that emits blue light by the use of the ink have been described above. However, the present disclosure should by no means be restricted by the above description except for its essential characteristic features. Modifications will hereinafter be described as examples of other aspects of the present disclosure.

(1) In the above-described embodiment, the blue light-emitting layer-forming ink was prepared by dissolving only the low-molecular anthracene-based solute in the tetralin-based solvent. One or more dopants may also be added in a range that does not significantly change the characteristics of the ink such as its high dissolution solubility and low viscosity characteristics.

(2) In the above-described embodiment, the organic EL element was manufactured as a top emission type with the opposite electrode acting as an anode. As an alternative example, however, the opposite electrode may act as a cathode, and the pixel electrodes may act as anodes. As another alternative example, the organic EL element may be of the bottom emission type.

(3) In the above-described embodiment, the organic EL element 2 was configured including the electron transport layer 18, the electron injection layer 19, the hole injection layer 15 and the hole transport layer 16. The organic EL element 2 is however not limited to this configuration. For example, the organic EL element 2 may be an organic EL element without the electron transport layer 18 or an organic EL element without the hole transport layer 16. Further, a hole injection/transport layer may be included as a single layer instead of the hole injection layer 15 and the hole transport layer 16. Furthermore, an intermediate layer formed from an alkali metal may be included, for example, between the light-emitting layer 17 and the electron transport layer 18.

(4) If a high-definition application of an ink through a nozzle is possible, a dispenser type coating machine, which continuously ejects the ink onto a substrate, may also be used without being limited to the printing apparatus in the above-described embodiment.

(5) The organic EL element according to the above-described embodiment can be not only what is called a pixel bank type organic EL element including banks formed in the shape of a lattice with individual subpixels surrounded by the banks, but also a line bank type organic EL element including banks formed in the shape of columns.

### <<Remarks>>

The blue light-emitting layer-forming ink and manufacturing method of the organic EL element that emits blue light, according to the first and second aspects of the disclosure, have been described above based on the embodiment and modifications. However, the present disclosure should not be limited to the above-described embodiment and modifications. The present disclosure also encompasses modes available by applying various modifications, which are conceivable to those skilled in the art, to the above-described embodiment and modifications, and modes realizable by combining the elements and functions of the above-described embodiment and modifications as desired within a scope not departing from the spirit of the present disclosure.

The present disclosure is most suitably applied to a blue light-emitting layer-forming ink useful in forming a blue light-emitting layer for an organic EL element by a printing process.

What is claimed is:

1. A blue light-emitting layer-forming ink useful in forming a blue organic light-emitting layer for an organic electroluminescent element by a printing process, comprising:
a tetralin-based organic solvent, and
a solute including an anthracene-based, low molecular material and dissolved at a concentration of 3% or higher and 12% or lower in the tetralin-based organic solvent.

2. The blue light-emitting layer-forming ink according to claim 1, wherein the solute with the anthracene-based, low molecular material included therein is dissolved at a concentration of higher than 7% and 12% or lower in the tetralin-based organic solvent.

3. The blue light-emitting layer-forming ink according to claim 1, wherein the anthracene-based, low molecular material has a weight average molecular weight of not higher than 3,000.

4. The blue light-emitting layer-forming ink according to claim 1, wherein the tetralin-based organic solvent is 1,2,3,4-tetrahydronaphthalene.

5. A manufacturing method of an organic electroluminescent element, comprising:
a first step of providing a substrate,
a second step of arranging a first electrode above the substrate,
a third step of forming an organic light-emitting layer above the first electrode, and
a fourth step of forming a second electrode above the organic light-emitting layer,
wherein the third step includes
a coating step of coating a blue light-emitting layer-forming ink, and a drying step of drying the coated light-emitting-layer forming ink, and
the blue light-emitting layer-forming ink comprises a tetralin-based organic solvent, and a solute including an anthracene-based, low molecular material and dissolved at a concentration of 3% or higher and 12% or lower in the tetralin-based organic solvent.

6. The manufacturing method according to claim 5, wherein the tetralin-based organic solvent is 1,2,3,4-tetrahydronaphthalene.
